(19) United States
(12) Patent Application Publication
(10) Pub. No.: US 2007/0291955 A1
(43) Pub. Date: Dec. 20, 2007

(54) Sound reproducing apparatus and sound synchronizing method in sound reproducing system

(75) Inventors: Makoto Yamashita, Akishima-shi (JP); Kenichi Ide, Akishima-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/806,409

(22) Filed: May 31, 2007

(30) Foreign Application Priority Data
May 31, 2006 (JP) 2006-151583

(51) Int. Cl. H04B 5/00; H03G 3/00

(52) U.S. Cl. 381/79; 381/104

(57) ABSTRACT

According to one embodiment, to provide a sound reproducing apparatus comprising a storage unit which stores content information therein, a communication unit which transmits the content information stored in the storage unit to an external device through wireless communication, a reproducing unit which reproduces the content information according to a set sound volume, an operation unit which outputs an operation signal for setting a reproducing sound volume, and a control unit which changes the set sound volume of the reproducing unit in response to the operation signal from the operation unit or sound volume information received by the communication unit, and which transmits sound volume information according to the set sound volume from the communication unit to the external device.

### CROSS-REFERENCE TO RELATED APPLICATIONS

This application is based upon and claims the benefit of priority from Japanese Patent Application No. 2006-151583, filed May 31, 2006, the entire contents of which are incorporated herein by reference.

### BACKGROUND

1. Field

One embodiment of the invention relates to a sound reproducing apparatus and a sound synchronizing method in a sound reproducing system, in which sound volume is synchronized among a plurality of sound reproducing apparatus through wireless communication such as Bluetooth®.

2. Description of the Related Art

As is well known, various electronic devices utilizing wireless communication are developed and produced, and become wide spread. In such electronic devices, a user operates a remote controller to supply various kinds of operation information to an electronic device body through the remote controller, which improves operability for the user.

For example, Jpn. Pat. Appln. KOKAI Publication No. 10-94070 discloses a composite mobile communication terminal in which remote control can be achieved by one remote controller and the switching is easily performed between a telephone and other functions.

In the conventional composite mobile communication terminal disclosed in Jpn. Pat. Appln. KOKAI Publication No. 10-94070, however, only the plural functions are simply switched by the remote controller. Therefore, there is no consideration of the way to solve the problem that sound volume information is supplied in a sound reproducing apparatus capable of reproducing audio contents both in a player body and a wireless headphone. Thus, even if a user adjusts the sound volume with one of the devices unless the sound volume information is synchronized, the setting is not reflected on the other device.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a view explaining an exemplary operation of a sound reproducing system according to an embodiment of the invention;

FIG. 2 is a block diagram showing an exemplary electric configuration of a wireless headphone according to an embodiment of the invention;

FIG. 3 is a block diagram showing an exemplary electric configuration of an audio player according to an embodiment of the invention;

FIG. 4 is a block diagram showing an exemplary electric configuration of a remote controller according to an embodiment of the invention;

FIG. 5 is a sequence chart showing an exemplary change process operation when a sound volume level is changed with the remote controller according to the embodiment of the invention;

FIG. 6 is a flowchart showing an exemplary change process operation when the sound volume level is changed with the audio player according to the embodiment of the invention;

FIG. 7 is a sequence chart showing an exemplary change process operation when the sound volume level is changed with the wireless headphone according to the embodiment of the invention; and

FIG. 8 is a sequence chart showing an exemplary change process operation when the sound volume level is changed with the audio player according to the embodiment of the invention.

### DETAILED DESCRIPTION

Various embodiments according to the invention will be described hereinafter with reference to the accompanying drawings. In general, according to one embodiment of the invention, a sound reproducing apparatus comprising: a storage unit which stores content information therein; a communication unit which transmits the content information stored in the storage unit to an external device through wireless communication; a reproducing unit which reproduces the content information according to a set sound volume; an operation unit which outputs an operation signal for setting a reproducing sound volume; and a control unit which changes the set sound volume of the reproducing unit in response to the operation signal from the operation unit or sound volume information received by the communication unit, and which transmits sound volume information according to the set sound volume from the communication unit to the external device.

In view of the foregoing, an object of the invention is to provide a sound reproducing apparatus and a sound synchronizing method in a sound reproducing system, wherein the sound volume setting can be synchronized among a plurality of sound reproducing apparatuses which transmit and receive music data through wireless communication.

According to an embodiment of the present invention, there is provided a sound reproducing apparatus comprising: a storage unit which stores content information therein; a communication unit which transmits the content information stored in the storage unit to an external device through wireless communication; a reproducing unit which reproduces the content information according to a set sound volume; an operation unit which outputs an operation signal for setting a reproducing sound volume; and a control unit which changes the set sound volume of the reproducing unit in response to the operation signal from the operation unit or sound volume information received by the communication unit, and which transmits sound volume information according to the set sound volume from the communication unit to the external device.

Therefore, the present invention can provide the sound reproducing apparatus and a sound synchronizing method in a sound reproducing system, wherein the sound volume setting can be synchronized among a plurality of sound reproducing apparatuses which transmit and receive music data through wireless communication.

A preferred embodiment of the invention will be described in detail below with reference to the drawings.

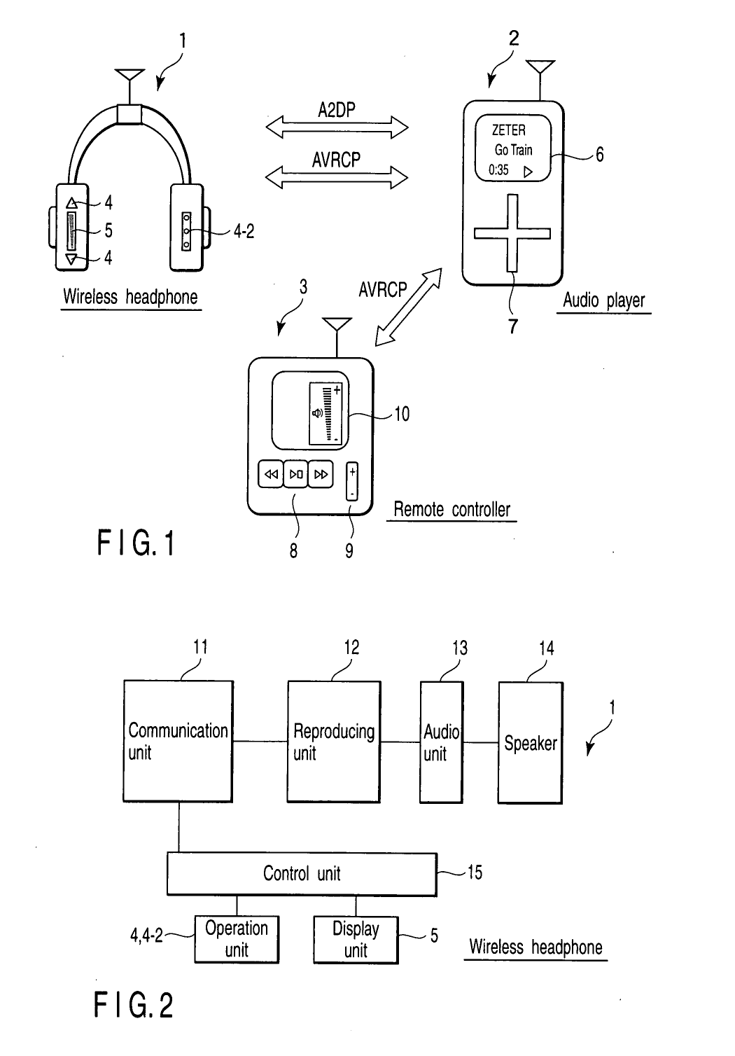

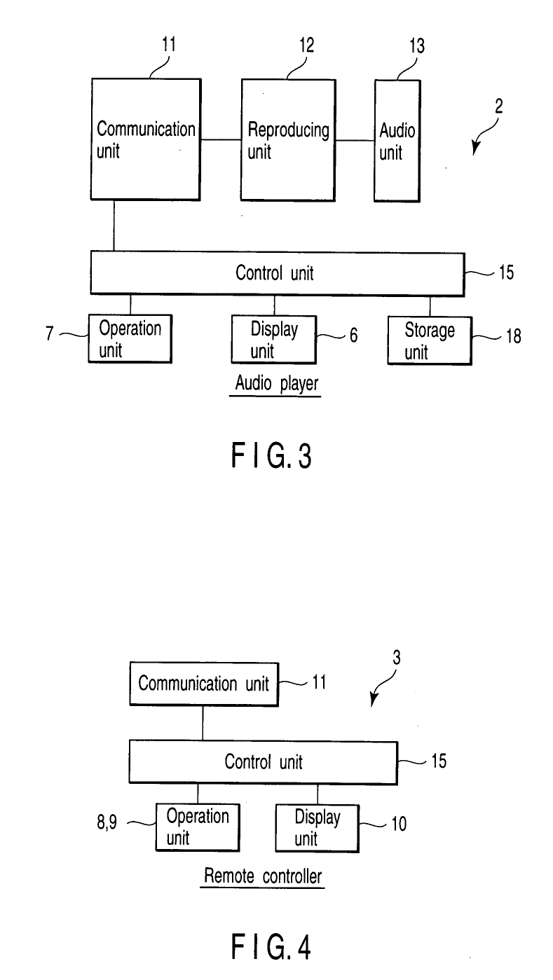

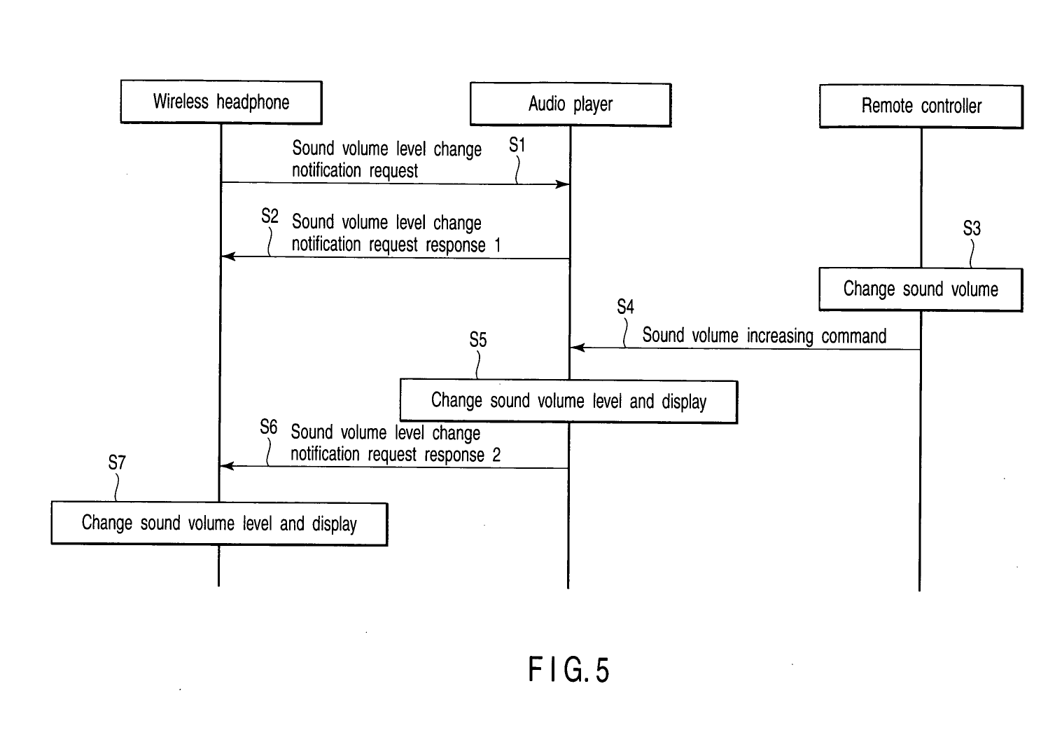

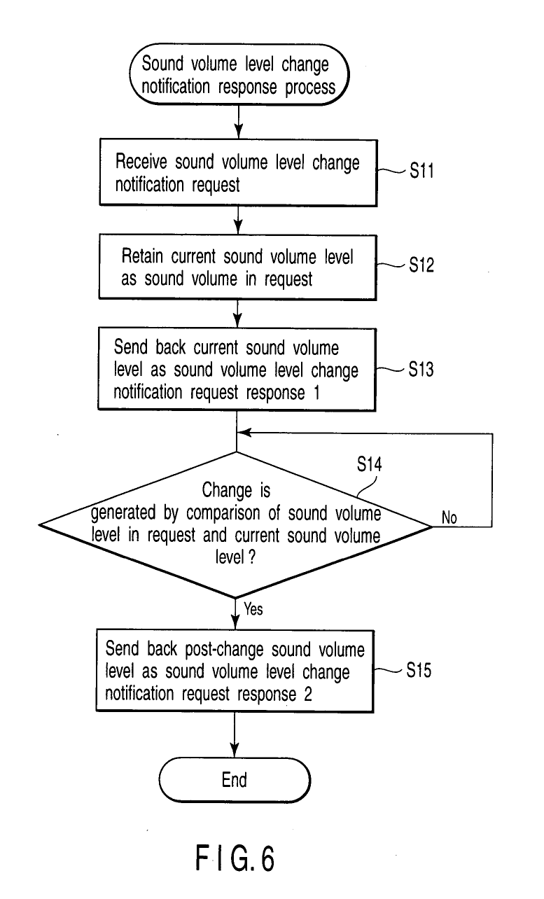

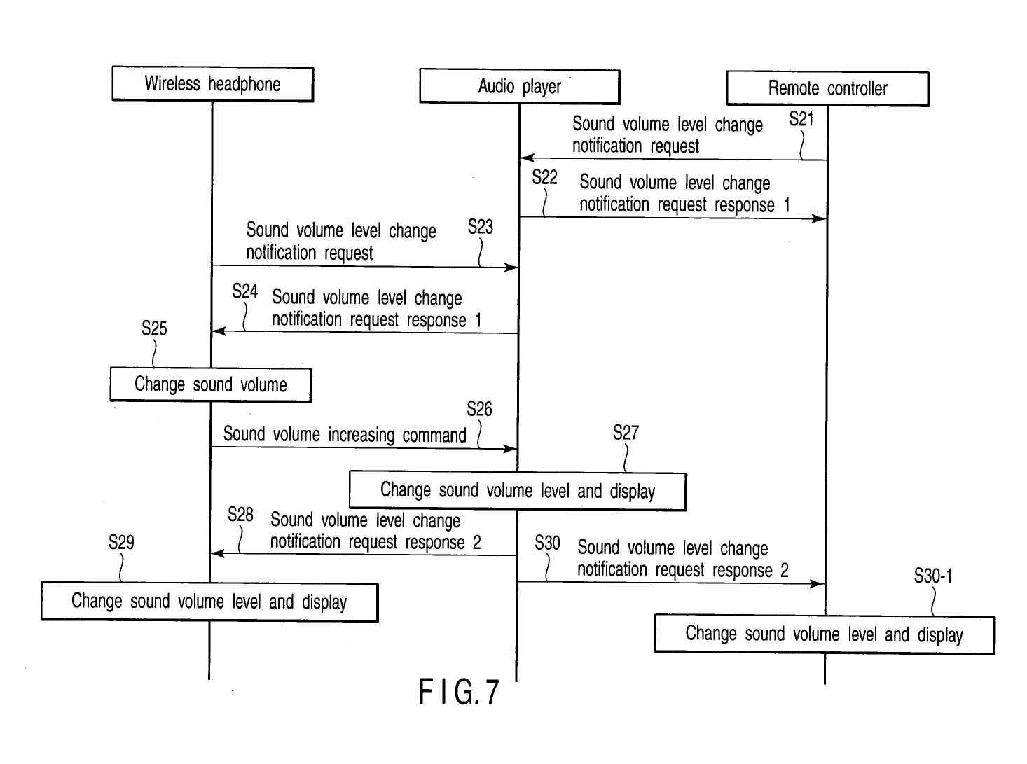

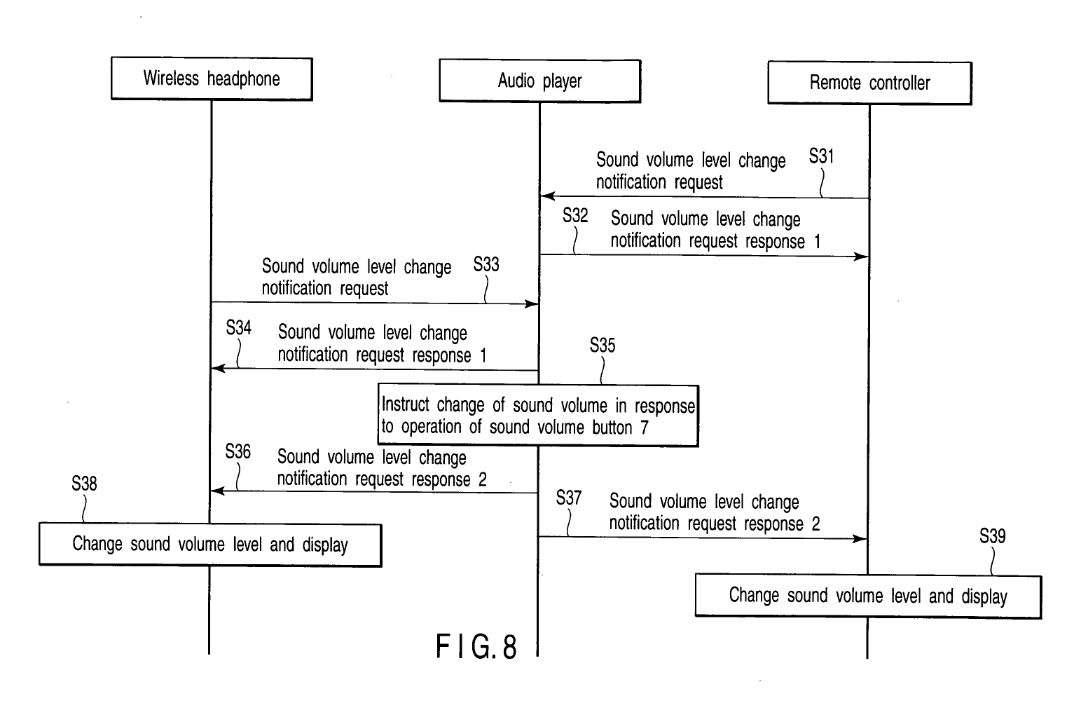

FIG. 1 is a view showing an exemplary operation of a sound reproducing system according to an embodiment of the invention. FIG. 2 is a block diagram showing an exemplary electric configuration of a wireless headphone of the embodiment. FIG. 3 is a block diagram showing an exemplary electric configuration of an audio player of the embodiment. FIG. 4 is a block diagram showing an exemplary electric configuration of a remote controller of the embodiment. FIG. 5 is a sequence chart showing an exemplary change process operation when a sound volume level is changed with the remote controller. FIG. 6 is a flowchart showing an exemplary change process operation when the sound volume level is changed with the audio player. FIG. 7 is a sequence chart showing an exemplary change process operation when the sound volume level is changed with the wireless headphone. FIG. 8 is a sequence chart showing an exemplary change process operation when the sound volume level is changed with the audio player.

### EXAMPLE OF SOUND REPRODUCING SYSTEM ACCORDING TO ONE EMBODIMENT OF THE INVENTION

### System Configuration

An outline and operation of the sound reproducing system of the embodiment will be described first. FIG. 1 shows configurations of a wireless headphone 1, an audio player 2, and a remote controller 3 of the embodiment.

(Configuration of Wireless Headphone)

The wireless headphone 1 of the embodiment is a general wireless headphone provided with a Bluetooth® communication function. The wireless headphone 1 includes a sound volume button 4 for adjusting a sound volume (hereinafter referred to as local sound volume) reproduced by the wireless headphone, a sound volume display unit 5, and a reproducing control button 4-2 for allowing a user to operate reproducing control.

An electric configuration of the wireless headphone 1 will be described with reference to FIG. 2. The wireless headphone 1 of the embodiment includes a communication unit 11 utilizing, for example, Bluetooth®, a reproducing unit 12, an audio unit 13, a speaker 14, a control unit 15, the display unit 5, and operation units 4 and 4-2. The reproducing unit 12 reproduces sound contents by a coding method such as sub band codec (SBC), advanced audio coding (AAC), and MPEG-1 Audio Level-3 (MP3). The audio unit 13 appropriately realizes sound volume, sound quality, and sound space. The speaker 14 receives an output from the audio unit 13. The control unit 15 controls the operation of the whole wireless headphone 1. The display unit 5 displays the sound volume or the like. The operation units 4 and 4-2 include the sound volume button 4 and the reproducing control button 4-2.

(Configuration of Audio Player)

An electric configuration of the audio player 2 will be described below with reference to FIGS. 1 and 3. The audio player 2 of the embodiment includes a communication unit 11 utilizing, for example, Bluetooth®; a reproducing unit 12 which reproduces music contents by a coding method such as SBC and MP3; an audio unit 13 which appropriately realizes sound volume, sound quality, and sound space; and a control unit 15 which controls the operation of the whole audio player 2. The audio player 2 also includes an operation unit 7 equipped with, for example, an arrow key, and a display unit 6. The operation unit 7 allows a user to perform various kinds of control and volume level adjustment of the audio player 2. The display unit 6 displays current tune information and the like.

(Configuration of Remote Controller)

An electric configuration of the remote controller 3 will be described below with reference to FIGS. 1 and 4. The remote controller 3 of the embodiment includes a communication unit 11 utilizing, for example, Bluetooth® and a control unit 15 which controls the operation of the whole remote controller 3. The remote controller 3 also includes operation units 8 and 9 and a display unit 10. The operation units 8 and 9 include a reproducing control button 8 for allowing a user to perform reproducing control of the audio player 2 connected through Bluetooth® and a sound volume button 9 for adjusting the sound volume of the audio player 2. The display unit 10 displays, for example, the information on a tune currently reproduced by the audio player 2 and the current sound volume level of the audio player.

(Operations)

The data is transmitted and received between the wireless headphone 1 and the audio player 2 such that the Bluetooth® communication units are connected in a wireless manner through antennas mounted in the communication units. The wireless headphone 1 and the audio player 2 communicates with each other by an advanced audio distribution profile (A2DP) which is a profile for transmitting sound data of Bluetooth® and an audio video remote control profile (AVRCP) which is a profile for transferring, for example, a control signal to perform remote control. At this point, the audio player 2 functions as a target (TG) of AVRCP while functioning as a transmission side (SRC) of A2DP.

The wireless headphone 1 functions as a controller (CT) of AVRCP while functioning as a reception side (SNK) of A2DP. Therefore, the music reproduced by the audio player 2 is transmitted to the wireless headphone 1 by A2DP, which allows the user to listen to the music by the wireless headphone 1 through the wireless communication.

The control signal according to the reproducing control button 4-2 incorporated into the wireless headphone 1 is transmitted as a command of AVRCP to the audio player 2, which allows the user to instruct various kinds of reproducing control (such as reproduction, stop, pause, forward, and rewind) to the audio player 2 from the wireless headphone 1 through the wireless communication.

In adjusting the sound volume of the music received by A2DP, the control is performed to increase or decrease the local sound volume of the wireless headphone 1 in conjunction with the operation of the sound volume button 4, which allows the user to suitably set the sound volume.

When the sound volume button 4 is pressed, the audio player 2 is notified of a sound volume increasing command or a sound volume decreasing command as a command of AVRCP.

The music data transmitted from the audio player 2 is music data output from a line-out or output from a digital output, and the music data has a constant sound volume. For this reason, the sound volume of the music data output from the audio player 2 to the wireless headphone 1 cannot be adjusted without operating simultaneously with the sound volume level of the audio player 2.

Data is transmitted and received between the audio player 2 and the remote controller 3 such that the Bluetooth® communication units are connected in a wireless manner through antennas mounted on the communication units. At this point, a set sound volume level is transmitted and received according to a scheme of the remote control by AVRCP of Bluetooth®. The audio player 2 functions as the target (TG) of AVRCP.

The remote controller 3 functions as a controller (CT) of AVRCP. A control signal according to the reproducing control button 8 incorporated into the remote controller 3 is transmitted as a command of AVRCP to the audio player 2. As a consequence, the user can instruct various kinds of reproducing control (such as reproduction, stop, pause, forward, and rewind) of the audio player 2 from the remote controller 3. Further, the user can operate the sound volume control button 9 to transmit a sound volume increasing signal and a sound volume decreasing signal from the remote controller 3 to the audio player 2 through the wireless communication.

However, as described above, the volume level change command provided from the remote controller 3 to the audio player 2 has an influence only on the local sound volume of the audio player 2, and the volume level change command has no influence on the sound volume of the music data transmitted to the wireless headphone 1 by A2DP.

In order to achieve the synchronization of the set sound volumes, each device of the embodiment transmits a sound volume level change notification reservation command to the device at the other end such that the device at the other end notifies each device of sound volume information when the sound volume setting is changed. The device having received the sound volume level change notification reservation command immediately transmits the current set sound volume and the sound volume information (hereinafter referred to as sound volume level change notification reservation response 1) in response to the sound volume level change notification reservation command, and the device transmits the post-change set sound volume as the sound volume information (hereinafter referred to as sound volume level change notification reservation response 2) when the set sound volume is changed.

It is assumed that the sound volume level change notification reservation command and the sound volume level change notification reservation responses 1 and 2 which are of the responses thereof are defined as a vender dependent command of AVRCP.

(Description of Operation with Flowchart)

Sound Volume Level Change Operation in Remote Controller

Description will be given to a process in which the sound volume of the wireless headphone 1 is changed through the audio player 2 in response to the sound volume increasing instruction from the remote controller 3, with reference to FIG. 5.

The wireless headphone 1 issues a sound volume level change notification request command to the audio player 2 (S1). The audio player 2 starts up a sound volume level change notification response process shown in FIG. 6, and the audio player 2 transmits the currently-retained sound volume level as the sound volume level change notification request response 1 to the wireless headphone 1 (S2).

Thereafter, it is assumed that the user operates the sound volume control button 9 of the remote controller 3 to increase the sound volume (S3). The remote controller 3 transmits the sound volume increasing command to the audio player 2 to increase the sound volume setting of the audio player 2 in response to the input of the sound volume increase (S4).

In accordance with the sound volume increasing command, the audio player 2 changes (increases) the currently-retained sound volume setting, and also changes the sound volume display on the display unit 6 (S5). Further, the audio player 2 notifies the wireless headphone 1 of the sound volume level as the sound volume level change notification request response 2 through a process of responding to the sound volume level change notification request received in S1 (S6).

The wireless headphone 1 matches the local sound volume level which is set by itself with the sound volume level which is notified by the audio player 2 (S7). Consequently, the local sound volume level of the wireless headphone 1 can indirectly be increased by the sound volume increasing control from the remote controller 3.

When the user operates the sound volume control button 9 of the remote controller 3, the processes from S1 are repeated.

Sound Volume Level Change Process in Audio Player

The sound volume level change notification response process performed by the audio player 2 will be described below with reference to FIG. 6.

When the audio player 2 receives the sound volume level change notification request (S11), the audio player 2 retains the current sound volume level as the sound volume level in the request (S12). Then, the audio player 2 sends back the current sound volume level retained in S12 as the sound volume level change notification response 1 to the other party having issued the sound volume level change notification request (S13).

The audio player 2 compares the current sound volume level to the sound volume level in the request retained in S12 by performing a monitoring process at constant intervals, and then determines whether or not the value is changed (S14). When the audio player 2 determines that the value is not changed (NO in S14), the audio player 2 performs the same comparison again. When the audio player 2 determines that the value is changed (YES in S14), the audio player 2 sends back the post-change sound volume level as the sound volume level change notification response 2 to the other party having issued the sound volume level change notification request (S15).

Sound Volume Level Change Operation in Wireless Headphone

A process in which the sound volume level is notified to the remote controller 3 through the audio player 2 by the sound volume control in the wireless headphone 1 will be described below with reference to FIG. 7.

The remote controller 3 issues the sound volume level change notification request command to the audio player 2 (S21). Consequently, the sound volume level change notification response process for the remote controller 3 is started up, and the audio player 2 transmits the currently-retained sound volume level as the sound volume level change notification request response 1 to the remote controller 3 (S22).

The wireless headphone 1 also issues the sound volume level change notification request command to the audio player 2 (S23). Consequently, the sound volume level change notification response process for the wireless headphone 1 is started up, and the audio player 2 transmits the currently-retained sound volume level as the sound volume level change notification request response 1 to the wireless headphone 1 (S24).

Then, when the user operates the sound volume control button 4 of the wireless headphone 1, the wireless headphone 1 transmits the sound volume increasing command to the audio player 2 (S26). The sound volume increasing command is of the command of AVRCP for increasing the sound volume of the audio player 2.

Therefore, the audio player 2 increases the set sound volume level, and updates the sound volume display of the display unit 6 (S27).

In accordance with the change in set sound volume, the audio player 2 notifies the wireless headphone 1 and the remote controller 3 of the changed sound volume level as the sound volume change notification request response 2 (S28 and S30).

Upon receipt of the sound volume level change notification request response 2, the remote controller 3 changes the set sound volume according to the post-change sound volume level, and also changes the sound volume display of the display unit 10 (S30-1).

Similarly, the wireless headphone 1 changes the set sound volume according to the post-change sound volume level, and the wireless headphone 1 also changes the sound volume display (S29).

In this manner, the local sound volume level of the wireless headphone 1 and the sound volume level displayed on the display unit 10 of the remote controller 3 can be synchronized with the sound volume level of the audio player 2.

Then, when the user operates the sound volume control button 4 of the wireless headphone 1, the processes from S21 to S31 are repeated.

Sound Volume Level Change Operation in Audio Player

A process in the case where the sound volume level of the audio player 2 is changed by the button operation of the audio player 2 will be described below with reference to FIG. 8.

The remote controller 3 issues the sound volume level change notification request command to the audio player 2 (S31). Consequently, the sound volume level change notification response process for the remote controller 3 is started up, and the audio player 2 transmits the currently-retained sound volume level as the sound volume level change notification request response 1 to the remote controller 3 (S32).

The wireless headphone 1 also issues the sound volume level change notification request command to the audio player 2 (S33). Consequently, the sound volume level change notification response process for the wireless headphone 1 is started up, and the audio player 2 transmits the currently-retained sound volume level as the sound volume level change notification request response 1 to the wireless headphone 1 (S34).

It is assumed that the user operates the sound volume button 7 of the audio player 2 to input the sound volume increasing instruction (S35). Consequently, the audio player 2 increases the set sound volume in itself. In accordance with the change in set sound volume, the audio player 2 notifies the wireless headphone 1 of the increased sound volume level as the sound volume level change notification request response 2 (S36). As a consequence, the wireless headphone 1 performs the process of changing the local sound volume level which is the set sound volume such that the local sound volume level is matched with the sound volume level notified by the audio player 2 (S38).

The audio player 2 also notifies the remote controller 3 of the increased sound volume level as the sound volume level change notification request response 2 (S37). Using the notified sound volume level, the remote controller 3 changes the set sound volume of the remote controller 3, and also updates the area where the sound volume level of the audio player 2 is displayed on the display unit 10 (S39).

Then, when the user operates the operation switch 7 of the audio player 2 to change the sound volume, the processes from S31 to S39 are repeated.

In the embodiment, the wireless headphone 1, the audio player 2, and the remote controller 3 are simultaneously connected to one another. Additionally, in the case where only the wireless headphone 1 and the audio player 2 are connected to each other, and in the case where the audio player 2 and the remote controller 3 are connected to each other, preferably the sound volume levels can be synchronized between two devices by the sound volume level change notification response process.

As described above, in the audio system of the embodiment, the sound volume of the device which is not directly connected can be controlled without establishing a wireless communication link by the sound volume synchronizing function in which the AVRCP vender dependent command is utilized, and the sound volume level can also be synchronized by the sound volume synchronizing function. Therefore, the user-friendliness of the device can be improved.

Furthermore, for the music data transmitted from the audio player 2 at constant sound volume, as if the sound volume setting of the audio player 2 were changed by the sound volume synchronizing function in which the AVRCP vender dependent command is utilized, which enables the local sound volume of the wireless headphone 1 to be changed.

Moreover, the sound volume levels can be synchronized with each other while a wireless communication link is not established between the wireless headphone 1 and the remote controller 3. Therefore, degradation of sound quality such as jumpiness can be prevented. The degradation of sound quality is caused by a decrease in communication rate generated when the wireless communication link is newly established between the wireless headphone 1 and the remote controller 3.

Although the invention has been described with reference to the preferred embodiment thereof, it will be understood by those skilled in the art that the foregoing and other changes can be made without departing from the spirit and scope of the invention. Accordingly, the invention is not limited to the embodiment, and the scope of the invention to be determined solely by the following claims.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A sound reproducing apparatus comprising:
a storage unit which stores content information therein;
a communication unit which transmits the content information stored in the storage unit to an external device through wireless communication;
a reproducing unit which reproduces the content information according to a set sound volume;
an operation unit which outputs an operation signal for setting a reproducing sound volume; and
a control unit which changes the set sound volume of the reproducing unit in response to the operation signal from the operation unit or sound volume information received by the communication unit, and which transmits sound volume information according to the set sound volume from the communication unit to the external device.

2. The sound reproducing apparatus according to claim 1, wherein the communication unit conducts wireless communication with the external device through Bluetooth®.

3. The sound reproducing apparatus according to claim 1, wherein the communication unit transmits the sound volume information to the external device by an audio video remote control profile (AVRCP) of Bluetooth®.

4. The sound reproducing apparatus according to claim 1, wherein the communication unit transmits the content information to the external device by an advanced audio distribution profile (A2DP) of Bluetooth®.

5. The sound reproducing apparatus according to claim 1, wherein the communication unit receives sound volume information from a second external device which is different from the external device, and
the control unit changes a set sound volume of the reproducing unit in response to the sound volume information received from the second external device by the communication unit, and transmits sound volume information according to the set sound volume from the communication unit to the external device.

6. A sound reproducing apparatus comprising:
a communication unit which receives content information and sound volume information from an external device through wireless communication;
a reproducing unit which reproduces the content information received by the communication unit according to a set sound volume;
a speaker which outputs sound reproduced by the reproducing unit; and
a control unit which changes a set sound volume of the reproducing unit based on the sound volume information given through the communication unit.

7. The sound reproducing apparatus according to claim 6, further comprising an operation unit which outputs an operation signal for setting a reproducing sound volume, wherein the control unit transmits the sound volume information from the communication unit to the external device when the set sound volume is changed in response to the operation signal from the operation unit.

8. The sound reproducing apparatus according to claim 6, wherein the communication unit conducts wireless communication with the external device through Bluetooth®.

9. The sound reproducing apparatus according to claim 6, wherein the communication unit transmits the sound volume information to the external device by an audio video remote control profile (AVRCP) of Bluetooth®.

10. The sound reproducing apparatus according to claim 6, wherein the communication unit receives the content information from the external device by an advanced audio distribution profile (A2DP) of Bluetooth®.

11. A sound volume synchronizing method of synchronizing set sound volumes in a sound reproducing system including a first sound reproducing apparatus and a second sound reproducing apparatus, at least one of the first and sound reproducing apparatuses having a storage unit which stores content information therein while the other apparatus having a speaker, the sound volume synchronizing method comprising;
changing a set sound volume of the first sound reproducing apparatus in response to an operation signal output from an operation unit;
transmitting sound volume information from the first sound reproducing apparatus to the second sound reproducing apparatus through wireless communication in response to the operation signal output from the operation unit;
changing a set sound volume of the second sound reproducing apparatus in response to the sound volume information received from the first sound reproducing apparatus; and
causing the first sound reproducing apparatus and the second sound reproducing apparatus to reproduce the content information stored in the storage unit to output sound from the speaker according to the set sound volume.

12. The sound volume synchronizing method according to claim 11, wherein the first sound reproducing apparatus and the second sound reproducing apparatus conduct wireless communication with each other through Bluetooth®.

13. The sound volume synchronizing method according to claim 11, wherein at least one of the first and second sound reproducing apparatuses conducts wireless communication by an audio video remote control profile (AVRCP) of Bluetooth®.

14. The sound volume synchronizing method according to claim 11, wherein at least one of the first and second sound reproducing apparatuses transmits the content information by an advanced audio distribution profile (A2DP) of Bluetooth®.

15. The sound volume synchronizing method according to claim 11, wherein the sound reproducing system further comprises a communication device provided with the operation unit, and the communication device transmits the operation signal output from the operation unit to the first sound reproducing apparatus.

16. The sound volume synchronizing method according to claim 11, wherein the first sound reproducing apparatus transmits the sound volume information to the communication device, and the communication device changes the set sound volume according to the sound volume information received from the first sound reproducing apparatus.
